(19) United States
(12) Patent Application Publication
(10) Pub. No.: US 2005/0016468 A1
(43) Pub. Date: Jan. 27, 2005

(54) Compensation frame for receiving a substrate

(76) Inventors: Guenther Ruhl, Neunkirchen am Brand (DE); Gerhard Prechtl, Ramerberg (DE); Winfried Sabisch, Munchen (DE); Alfred Kersch, Putzbrunn (DE); Pavel Nesladek, Garching (DE); Fritz Gans, Grossrohrsdorf (DE); Rex Anderson, Raleigh, NC (US)

Correspondence Address: SHAW PITTMAN LLP, 14th Floor, 1650 Tysons Boulevard, McLean, VA, 22012-4859, US

(21) Appl. No.: 10/742,763

(22) Filed: Dec. 23, 2003

(30) Foreign Application Priority Data
Dec. 23, 2002 (DE) 102 60 645.5

(51) Int. Cl. C23C 16/00

(52) U.S. Cl. 118/728

(57) ABSTRACT

An inner contour of the compensation frame (2) is configured in polygonal fashion in order to receive the substrate (1). With the substrate (1) having been received, the compensation frame (2) encloses the substrate (1) at the outer edge thereof. A partial region (3a) of an upper main area (3) of the compensation frame (2) runs at a given height (h) above the plane of an upper main area (1a) of the substrate (1) when the latter has been received into the compensation frame (2). Moreover, a further partial region (3b) of the upper main area (3) of the compensation frame runs essentially at the same height as the plane of the upper main area (3) of the substrate (1) when the latter has been received into the compensation frame (2).

The present invention relates to a compensation frame for receiving a substrate.

In the field of semiconductor technology, inter alia various gas phase etching processes (e.g. of chemical or ionic nature) are also used for the controlled etching of substrates. Such substrates may be semiconductor wafers which serve for fabricating semiconductor components, or alternatively photomasks to be fabricated, which are then used later, after they have been completed, in the fabrication of the semiconductor components inter alia in the context of exposure processes. During these etching processes, endeavors are always made to achieve an as far as possible uniform concentration distribution of the etchants, i.e. of the reactive species, across the substrate to be etched. In this case, problems are posed by the edge region of the substrate, since here, on account of the geometrical conditions, the etching rate is generally different than, for example, in the center of the substrate. Thus, at the edge region of the substrate, a different concentration of the reactive species is established than in the center region of the substrate to be etched.

In cases in which the substrate to be etched is a semiconductor wafer, a remedy has been provided heretofore using so-called focus rings. This is disclosed e.g. in U.S. Pat. No. 5,685,914 and in U.S. Pat. No. 5,976,310. However, the desired success is established only in the case of substrates with a circular main surface, but not in the case of substrates configured geometrically differently, such as e.g. in the case of photomasks, which generally have a rectangular or square main surface.

Therefore, it an object of the present invention to provide an apparatus with the aid of which, during etching operations with regard to a substrate with a non-round main surface, an as far as possible uniform concentration distribution is established over the substrate.

This object is achieved by means of a compensation frame having the features of patent claim 1. Advantageous designs and developments of the invention are characterized in subclaims.

The invention is explained in more detail below with reference to a drawing, in which

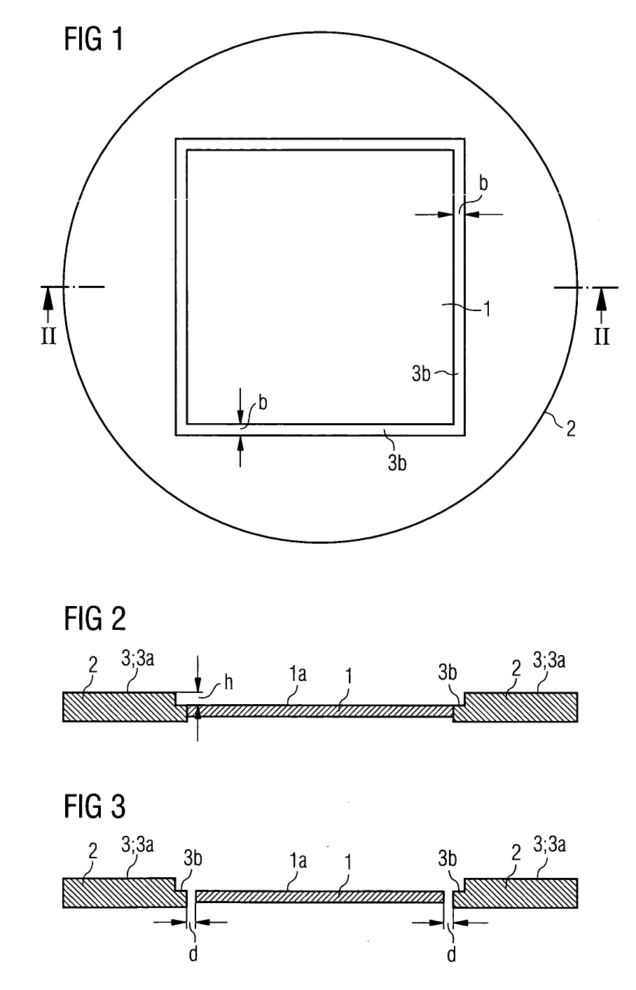

FIG. 1 shows a first embodiment of the compensation frame according to the invention and also a substrate introduced therein, both respectively in plan view,

FIG. 2 shows a cross section through the compensation frame with the substrate according to FIG. 1,

FIG. 3 shows a cross section through a second embodiment of the compensation frame according to the invention together with a received substrate, and

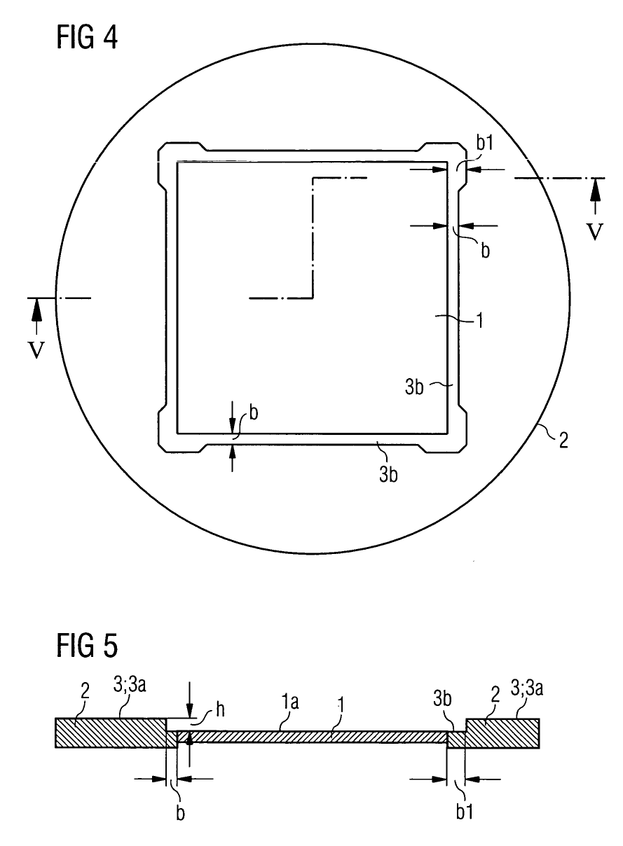

FIGS. 4 to 7 show a third and a fourth embodiment together with a respectively inserted substrate, respectively in plan view and in cross section.

FIG. 1 shows a first embodiment of the compensation frame according to the invention in plan view. A polygonal substrate 1, for example a quadrangular photomask to be fabricated, which is intended to be subjected to an etching operation during its fabrication process, is arranged within the compensation frame 2. In order that the substrate 1 can be received within the compensation frame 2, the inner contour of the compensation frame 2 is configured in polygonal fashion according to the invention and is quadrangular in the first embodiment illustrated in FIG. 1. The substrate 1 is enclosed by the compensation frame 2 at its outer edge.

The first embodiment—illustrated in FIG. 1—of the compensation frame 2 according to the invention and the substrate 1 are illustrated in a cross section in FIG. 2. The cross section is taken along the line II-II illustrated in FIG. 1. FIG. 2 reveals that an upper main area 3 of the compensation frame 2 according to the invention runs at different heights with regard to an upper main area 1a of the substrate 1: a first partial region 3a of the upper main area 3 of the compensation frame according to the invention runs at a given height h, which is at least 5 mm, for example, above the upper main area 1a of the substrate 1. A further partial region 3b of the upper main area 3 of the compensation frame 2 according to the invention runs essentially at the same height as the upper main area 1a of the substrate 1. Said further partial region 3b has a constant width b, which preferably lies in a range of 1 mm to 30 mm. The concentration of the reactive species may be modulated locally e.g. by recombination at the walls of the compensation frame or by influencing the electric field in a plasma etching process. This is advantageous if a nonuniform distribution of the species to be etched on the substrate gives rise to local depletion effects of the reactive species. This is equally advantageous in the case of an etching gas comprising a plurality of components. In the case of a differently nonuniform distribution of the reactive components (e.g. gradient in a reactive plasma) it is possible, e.g. given a different recombination coefficient of the two reactive components at the compensation frame surface, through a suitable embodiment of the compensation frame, for the two concentration profiles to be matched to one another (e.g. Cl and O radicals in the plasma etching of chromium for photomask fabrication). Since the corners of a quadrangular substrate are exposed to a different flow of reactive species than the edges, it is advantageous, under certain circumstances, to embody the distance b between substrate and compensation frame such that it deviates locally in the corner region. This is because the concentration of the species is influenced during etching by an interaction (e.g. by recombination) of the species with the compensation frame 2. This influence is set by the effect of the width b in conjunction with the height h.

The first embodiment of the compensation frame 2 according to the invention as shown in FIGS. 1 and 2 is dimensioned in such a way that, with the substrate 1 having been received, it directly adjoins said substrate. FIG. 3, by contrast, shows a second embodiment of the compensation frame 2 according to the invention in which a received substrate 1 is enclosed at a given distance d. Said distance d is expediently 1 mm to 4 mm.

FIG. 4 shows a third embodiment of the compensation frame 2 according to the invention. It differs from the first embodiment illustrated in FIGS. 1 and 2 in the configuration of the further partial region 3b: said further partial region 3b has a larger width b1 at some locations, which are arranged at the inner corners of the compensation frame 2 in FIG. 4, than at the other locations of the further partial region 3b, the width of which is designated by the letter “b” already used above. This third embodiment otherwise corresponds to the first embodiment, illustrated in FIGS. 1 and 2.

FIG. 5 shows the third embodiment of the compensation frame 2 according to the invention in a cross section taken along a line V-V depicted in FIG. 4. FIG. 5 also reveals the different widths b and b1, which may advantageously both vary in the range of 1 mm to 30 mm. In this case, however, it is favorable for the two mutually different widths b, b1 to have a difference of at least 0.5 mm.

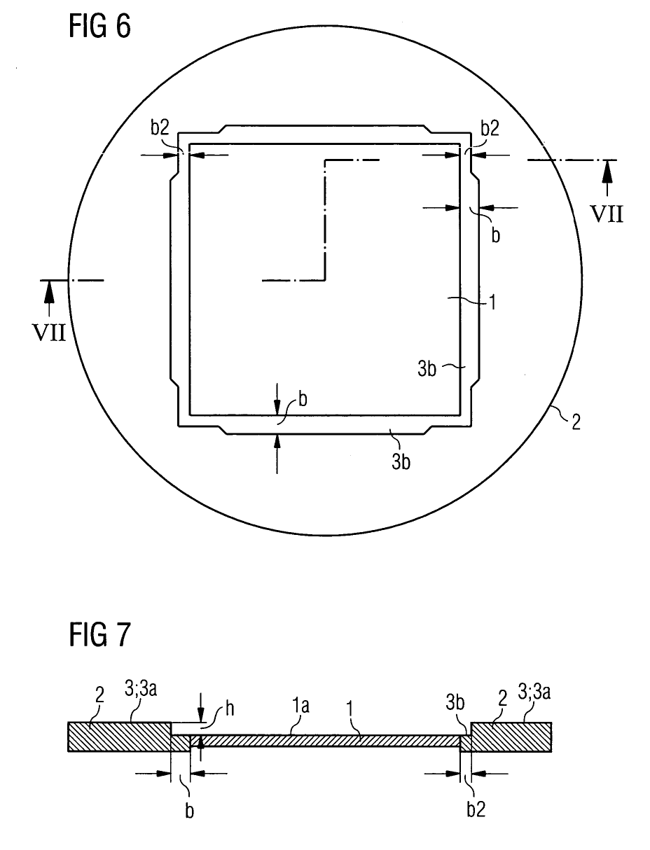

FIGS. 6 and 7 show a fourth embodiment of the compensation frame 2 according to the invention, which is very similar to the third embodiment described above: here, however, the first locations of the mutually different locations have a smaller width b2 than the width b at the other locations of the mutually different locations. Here, the first locations are likewise arranged in the region of the inner corners of the compensation frame 2 according to the invention. Here, too, the widths b and b2 are advantageously 1 mm to 30 mm, a difference between said widths b, b2 of at least 0.5 mm prevailing. The cross section through the compensation frame 2 according to the invention as shown in FIG. 7 is taken along the line VII-VII illustrated in FIG. 6.

The above-described embodiments of the compensation frame 2 according to the invention are in each case shown in the drawing, in those figures in which they are illustrated in plan view, in such a way that the outer contour of the compensation frame 2 according to the invention is circular. This could, however, also be different, e.g. quadrangular.

List of Reference Symbols

1 Substrate
1a Upper main area of the substrate
2 Compensation frame
3 Upper main area of the compensation frame
3a, 3b Partial regions of the compensation frame
b, b1, b1 Width
d Distance
h Height

1. A compensation frame for receiving a substrate (1) comprising:
an inner contour of the compensation frame (2) configured in polygonal fashion in order to receive the substrate 1;
with the substrate (1) having been received, the compensation frame (2) encloses the substrate (1) at the outer edge thereof;
wherein a partial region (3a) of an upper main area (3) of the compensation frame (2) runs at a given height (h) above the plane of an upper main area (1a) of the substrate (1) when the latter has been received into the compensation frame (2); and
wherein a further partial region (3b) of the upper main area (3) of the compensation frame (2) runs essentially at the same height as the plane of the upper main area (1a) of the substrate (1) when the latter has been received into the compensation frame (2).

2. The compensation frame as claimed in claim 1, wherein:
the compensation frame is dimensioned in such a way that, with the substrate (1) having been received, it directly adjoins the substrate (1) along the entire inner contour.

3. The compensation frame as claimed in claim 1, wherein:
the compensation frame is dimensioned in such a way that, with the substrate (1) having been received, it encloses said substrate at a given distance (d).

4. The compensation frame as claimed in claim 3, wherein:
the given distance (d) is from 1 to and including 4 mm.

5. The compensation frame as claimed in claim 1, wherein:
the given height (h) at which the partial region (3a) of the plane of the upper main area (3) of the compensation frame (2) runs above the upper main area (1a) of the substrate (1) is at least 5 mm.

6. The compensation frame as claimed in claim 1, wherein:
the further partial region (3b) of the upper main area (3) of the compensation frame (2) has a width (b) which is constant.

7. The compensation frame as claimed in claim 1, wherein:
the further partial region (3b) of the upper main area (3) of the compensation frame (2) has a width (b) which is from 1 to and including 30 mm.

8. The compensation frame as claimed in claim 1, wherein:
the further partial region (3b) of the upper main area (3) of the compensation frame (2) has different widths (b, b1, b2) at mutually different locations.

9. The compensation frame as claimed in claim 8, wherein:
the first locations of the mutually different locations have a larger width (b1) than the other locations.

10. The compensation frame as claimed in claim 8, wherein:
the first locations of the mutually different locations have a smaller width (b2) than the other locations.

11. The compensation frame as claimed in claim 8, wherein:
the first locations are arranged at corners of the compensation frame (2).

12. The compensation frame as claimed in claim 8, wherein:
the different widths (b, b1, b2) are from 1 to and including 30 mm.

13. The compensation frame as claimed in claim 8, wherein:
the different widths (b, b1, b2) differ from one another by at least 0.5 mm.

14. The compensation frame as claimed in claim 1, wherein:
the inner contour is quadrangular.

15. The compensation frame of claim 9, wherein:
the first locations are arranged at corners of the of the compensation frame (2).

16. The compensation frame of claim 8, wherein:
the inner contour is quadrangular.

17. The compensation frame of claim 9, wherein:
the first locations are arranged at corners of the compensation frame (2).

18. The compensation frame of claim 10, wherein:
the first locations are arranged at corners of the compensation frame (2).

19. A compensation frame for receiving a quadrangular photomask substrate for processing, comprising:
an inner contour of the compensation frame (2) configured in polygonal fashion in order to receive the substrate (1);
with the substrate (1) having been received, the compensation frame (2) encloses the substrate (1) at the outer edge thereof;
wherein a partial region (3a) of an upper main area (3) of the compensation frame (2) runs at a given height (h) above the plane of an upper main area (1a) of the substrate (1) when the latter has been received into the compensation frame (2); and
wherein a further partial region (3b) of the upper main area (3) of the compensation frame (2) runs essentially at the same height as the plane of the upper main area (1a) of the substrate (1) when the latter has been received into the compensation frame (2).

20. The compensation frame of claim 19, wherein the compensation frame (2) is dimensioned to directly adjoin the photomask substrate (1) along the inner contour after the photomask substrate (1) is received into the compensation frame (2).
